(19) United States
(12) Patent Application Publication
(10) Pub. No.: US 2015/0070819 A1
(43) Pub. Date: Mar. 12, 2015

(54) SERVER POWER SUPPLY SYSTEM

(71) Applicant: ACBEL POLYTECH INC., New Taipei City (TW)

(72) Inventors: Yung-Han KUO, New Taipei City (TW); Hsin-Yan CHIEN, New Taipei City (TW)

(73) Assignee: ACBEL POLYTECH INC., New Taipei City (TW)

(21) Appl. No.: 14/178,639

(22) Filed: Feb. 12, 2014

(30) Foreign Application Priority Data
Sep. 9, 2013 (TW) 102132393

(51) Int. Cl. H05K 7/20; H05K 5/02

(52) U.S. Cl. CPC H05K 7/20718; H05K 7/20709; H05K 5/0247
USPC 361/622; 312/223.2

(57) ABSTRACT

A power supply system has a housing and a front panel. The housing has multiple power supply slots disposed on a rear of the housing for mounting multiple power supplies respectively. The front panel has multiple peak portions and multiple valley portions arranged alternately to form a multi-dimensional space. Each peak portion has a first inclined wall for mounting multiple terminal holders, and has a second inclined wall for forming a heat dissipating structure. Electric power is input into the server power supply system via the terminal holder and is transformed and transmitted to the power supplies. With the terminal holders and the heat dissipating structures disposed on the peak portions of the front panel, space of the front of the housing can be utilize efficiently and heat dissipating efficiency to the server power supply system is also improved.

### BACKGROUND OF THE INVENTION

1. Field of the Invention

The present invention relates to a power supply system, especially to a server power supply system that has a housing with a multi-dimensional space for disposing terminal holders and heat dissipating structures, and reconciling both wiring and heat dissipating efficiency.

2. Description of the Prior Art(s)

A rack server is modularly designed in order to be mounted in a cabinet, and is optimized to minimize the use of physical space. The rack server further has multiple power supply systems and multiple server systems with multiple input/output (I/O) cables. The server systems and the power supply systems are mounted in the cabinet. In the modularly designed rack server, the I/O cables extend out from a rear of the cabinet.

With further reference to FIG. 9, each of the power supply systems has a housing 90, a power distribution module, a power input panel 91, multiple terminal holders 93, and multiple power supplies 92. The power distribution module is mounted in the housing 90. The power input panel 91 is substantially flat and is mounted on a front of the housing 90. The terminal holders 93 are mounted on the power input panel 91 and are electrically connected to the power distribution module. The power supplies 92 are mounted on a rear of the housing 90 and are electrically connected to the power distribution module. Multiple power input cables are respectively connected to the terminal holders 93 to input electric power into the power supply system. The power distribution module distributes the electric power to the power supplies 92 to transform voltage of the electric power. Then the power supplies 92 supply the voltage-transformed electric power to the server systems respectively.

Since the rack server and the cabinet have predefined sizes, the power supply system that is mounted in the cabinet also has a predefined size. As a height of the housing 90 of the power supply system has been predefined, the power supplies 92 have to be stacked and arranged side by side in the housing 90 in order to mount as many power supplies 92 as possible on the housing 90.

Under the above-mentioned arrangement, two sides of each power supply 92 are practically enclosed. Heat generated on each power supply 92 can only be dissipated from a front end and a rear end of each power supply 92. As each power supply 92 further has a fan module 920 and the fan module 920 produces an air current flowing toward the housing 90, the housing 90 has to have sufficient heat dissipating path so the heat in the housing 90 can be dissipated. However, since the flat power input panel 91 that is mounted on the front of the housing 90 is used for mounting the terminal holders 93, if multiple heat dissipating holes are formed on the power input panel 91 to dissipate heat in the housing 90, the number of the terminal holders 93 would be reduced.

To overcome the shortcomings, the present invention provides a server power supply system to mitigate or obviate the aforementioned problems.

### SUMMARY OF THE INVENTION

The main objective of the present invention is to provide a server power supply system. The power supply system has a housing and a front panel. The housing has a front, a rear, and multiple power supply slots. The power supply slots are disposed on the rear of the housing for mounting multiple power supplies respectively. The front panel has multiple peak portions and multiple valley portions arranged alternately to form a multi-dimensional space. Each peak portion has a first inclined wall for mounting multiple terminal holders, and has a second inclined wall for forming a heat dissipating structure.

Electric power is input into the server power supply system via the terminal holder and is transformed and transmitted to the power supplies. With the terminal holders and the heat dissipating structures disposed on the peak portions of the front panel, space of the front of the housing can be utilized efficiently and heat dissipating efficiency to the server power supply system is also improved.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a server power supply system in accordance with the present invention;

FIG. 2 is an exploded perspective view in partial section of the server power supply system in FIG. 1;

FIG. 3 is an operational perspective view of the server power supply system in FIG. 1, showing multiple power supplies mounted thereon;

FIG. 4 is a cross-sectional side view of a front panel of the server power supply system in FIG. 1;

FIG. 5 is another exploded perspective view in partial section of the server power supply system in FIG. 1;

FIG. 6 is an enlarged side view in partial section of the server power supply system in FIG. 1;

FIG. 7 is an enlarged side view of the server power supply system in FIG. 1;

FIG. 8 is an enlarged front view of the server power supply system in FIG. 1; and

FIG. 9 is a perspective view of a conventional server power supply system in accordance with the prior art.

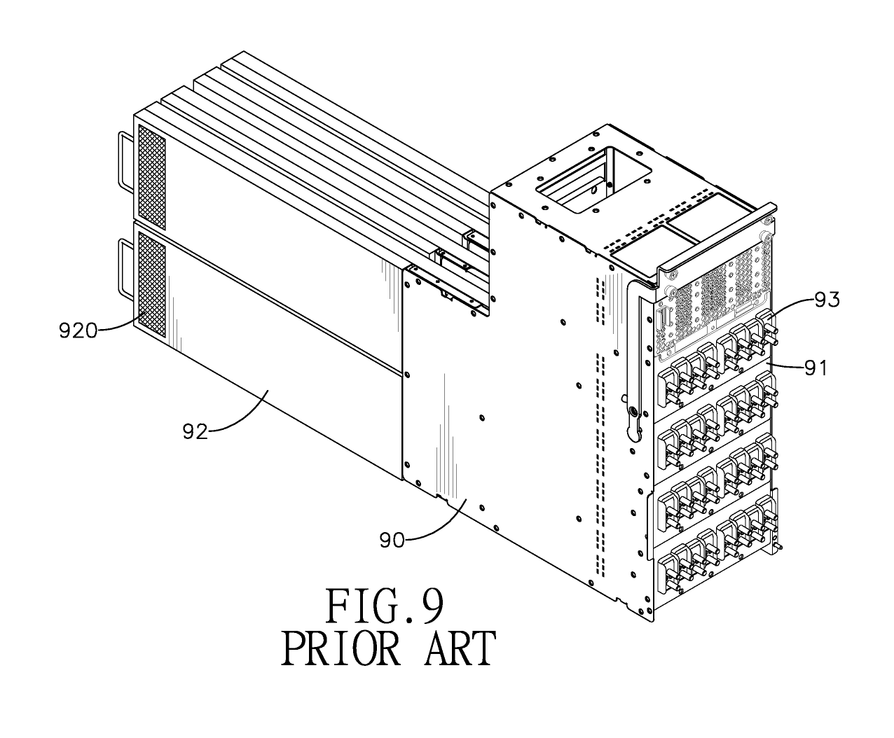

### DETAILED DESCRIPTION OF THE PREFERRED EMBODIMENTS

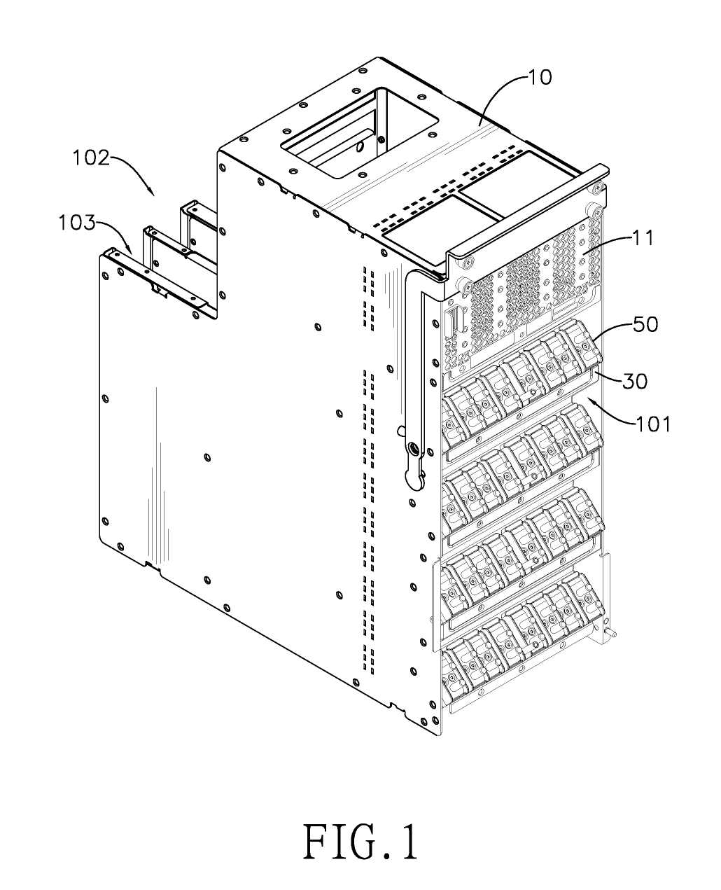

With reference to FIGS. 1 to 3, a server power supply system in accordance with the present invention comprises a housing 10, multiple power supplies 20, at least one front panel 30, multiple terminal holders 50, and a power distribution module 40.

The housing 10 has a front 101, a rear 102, multiple power supply slots 103, and an apertured panel 11. The power supply slots 103 are disposed on the rear 102 of the housing 10. Each of the power supply slots 103 has an upper portion 103A and a lower portion 103B. The apertured panel 11 is mounted on the front 101 of the housing 10.

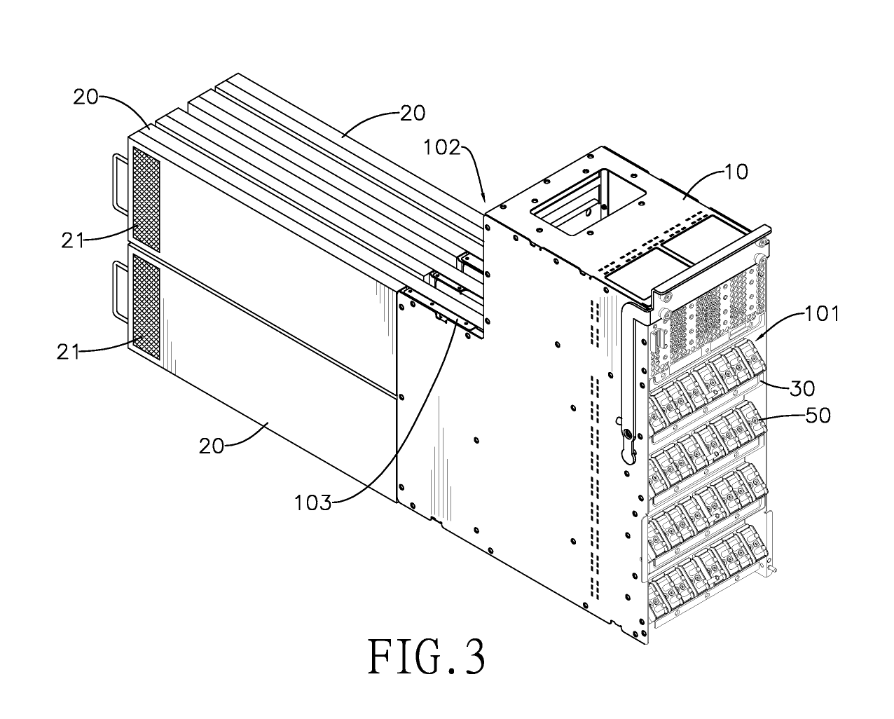

As shown in FIG. 3, the power supplies 20 are arranged side by side and stacked on the rear 102 of the housing 10, and are respectively mounted in the upper portions 103A and the lower portions 103B of the power supply slots 103. Each of the power supplies 20 has an outer end, an inner end, and a fan module 21. The inner end of the power supply 20 is mounted in the power supply slot 103. The fan module 21 is mounted in the outer end of the power supply 20 and generates an air current flowing toward the front 101 of the housing 10 to dissipate heat.

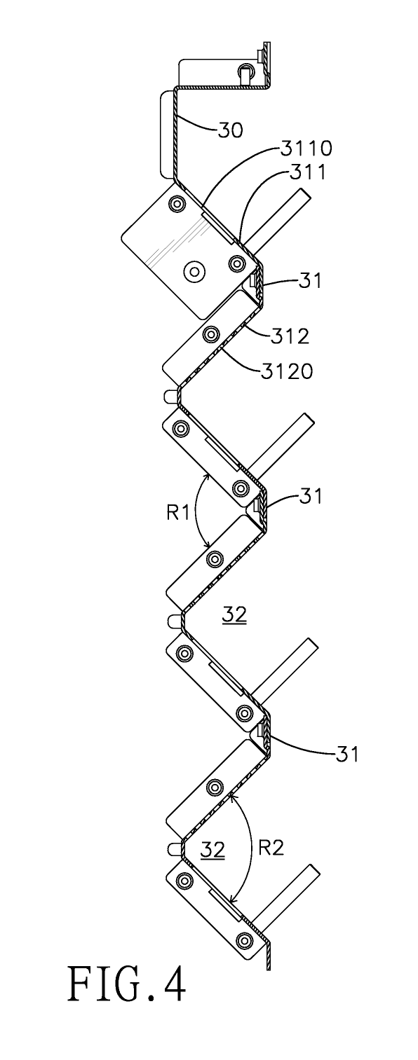

With further reference to FIG. 4, the at least one front panel 30 is mounted on the front 101 of the housing 10 and is disposed below the apertured panel 11. Each of the at least one front panel 30 has multiple peak portions 31 and multiple valley portions 32. The peak portions 31 and the valley portions 32 are arranged alternately.

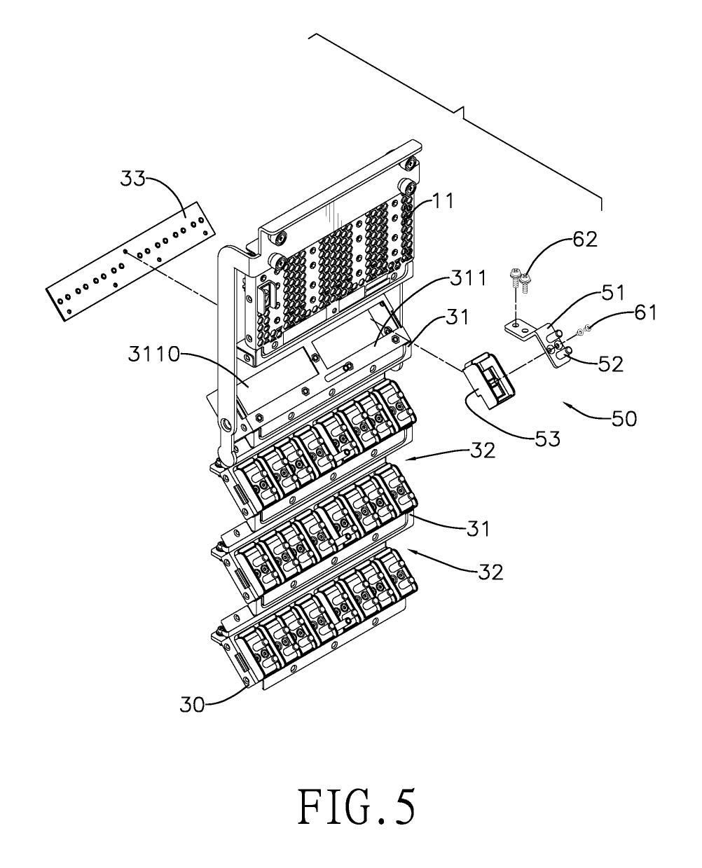

With further reference to FIG. 5, each peak portion 31 protrudes forwardly and has a first inclined wall 311, a second inclined wall 312, a first included angle R1, a holder mounting structure, and a heat dissipating structure. The first inclined wall 311 has an outer surface and an inner surface corresponding to an interior of the housing 10. The second inclined wall 312 has an outer surface and an inner surface corresponding to the interior of the housing 10. The first included angle R1 is defined between the inner surface of the first inclined wall 311 and the inner surface of the second inclined wall 312 of the peak portion 31, and is adjustable.

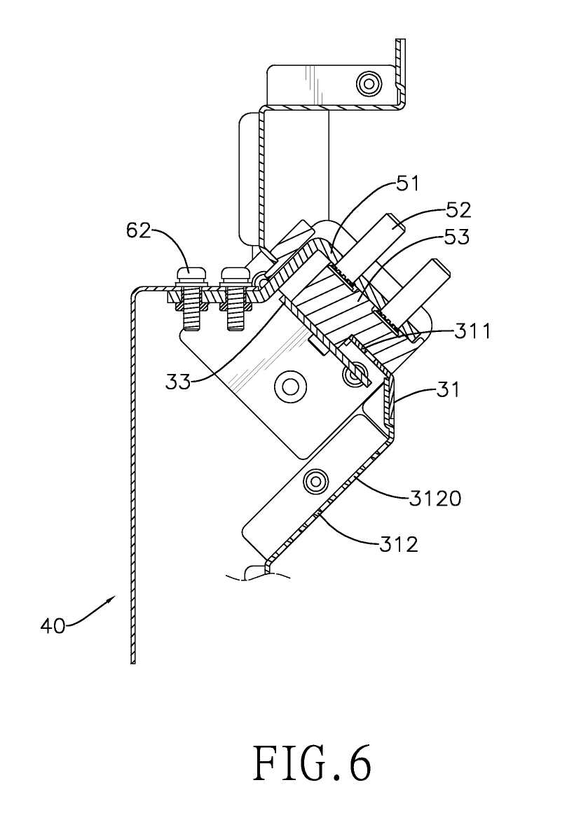

With further reference to FIG. 6, the holder mounting structure is formed on the first inclined wall 311 and includes at least one opening 3110 and a mounting panel 33. The at least one opening 3110 is formed through the first inclined wall 311. The mounting panel 33 is securely mounted on the inner surface of the first inclined wall 311 and corresponds to the at least one opening 3110 in location. The heat dissipating structure is formed on the second inclined wall 312 and includes multiple heat dissipating holes 3120 densely arranged on and formed through the second inclined wall 312.

Each valley portion 32 is formed between the second inclined wall 312 of one of the peak portions 31 and the first inclined wall 311 of the next peak portion 31, and has a second included angle R2. The second included angle R2 is defined between the outer surface of the second inclined wall 312 of one of the peak portions 31 and the outer surface of the first inclined wall 311 of the next peak portion 31, and is adjustable.

Specifically, each of the first included angles R1 may be 90 degrees, and each of the second included angles R2 may be 90 degrees.

The terminal holders 50 are mounted on the holder mounting structures of the first inclined walls 311 of the peak portions 31 of the at least one front panel 30. Each terminal holder 50 has a base 53, a conducting terminal 51, and at least one conducting protrusion 52. The base 53 is securely mounted on the holder mounting structure of the first inclined wall 311. The conducting terminal 51 is mounted in the base 53 and has a first end and a second end. The first end of the conducting terminal 51 is mounted in the base 53 and is securely attached to the base 53 and the mounting panel 33 via fasteners 61. The second end of the conducting terminal 51 is bent relative to the first end of the conducting terminal 51, and protrudes through the base 53 and toward the interior of the housing 10. The at least one conducting protrusion 52 is formed on and protrudes from the first end of the conducting terminal 51.

Preferably, each of the at least one opening 3110 of the holder mounting structure may be rectangular and the base 53 of each terminal holder 50 may be rectangular. A length of the base 53 corresponds to a width of the opening 3110, such that the multiple terminal holders 50 are mounted in and are arranged along each of the openings 3110.

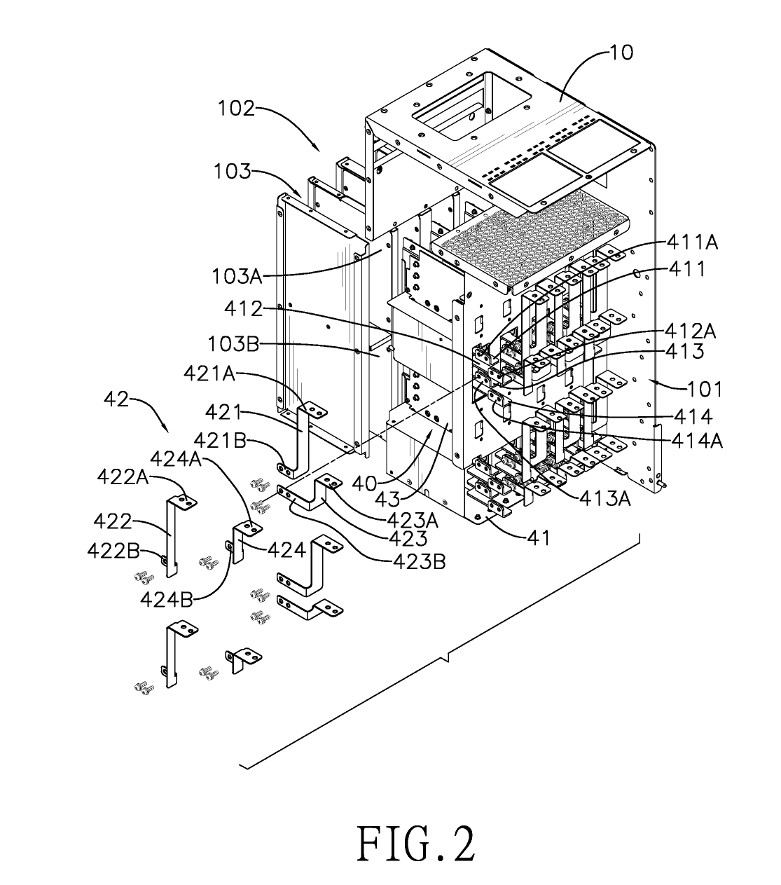

As shown in FIG. 2, the power distribution module 40 is mounted in the housing 10, is electrically connected to the second ends of the conducting terminals 51 of the terminal holders 50 via fasteners 62, and has multiple circuit boards 43, multiple connecting terminal assemblies 41, and multiple intermediate terminal assemblies 42. The circuit boards 43 are mounted in the housing 10. The connecting terminal assemblies 41 are respectively connected electrically to the circuit boards 43. The intermediate terminal assemblies 42 respectively connect the conducting terminals 51 of the terminal holders 50 to the connecting terminal assemblies 41. Thus, when electric power is input into the power distribution module 40 via the terminal holders 50, the electric power is transmitted to the circuit boards 43 through the intermediate terminal assemblies 42 and the connecting terminal assemblies 41. The circuit boards 43 transform voltage of the electric power and distribute the voltage-transformed electric power to the power supplies 20.

Specifically, each of the connecting terminal assemblies 41 includes multiple connecting terminals 411, 412, 413, 414. The connecting terminals 411, 412, 413, 414 are longitudinally arranged. Each of the connecting terminals 411, 412, 413, 414 extends transversely and has a front end and a rear end. The rear ends of the connecting terminals 411, 412, 413, 414 are connected to the circuit board 43.

In the preferred embodiment, each of the connecting terminals 411, 412, 413, 414 further has a connecting portion 411A, 412A, 413A, 414A protruding up from the front end of the connecting terminal 411, 412, 413, 414. The connecting terminals 411, 412, 413, 414 of each connecting terminal assembly 41 are two short connecting terminals 411, 413 and two long connecting terminals 412, 414. The short connecting terminals 411, 413 and the long connecting terminals 412, 414 are arranged alternately.

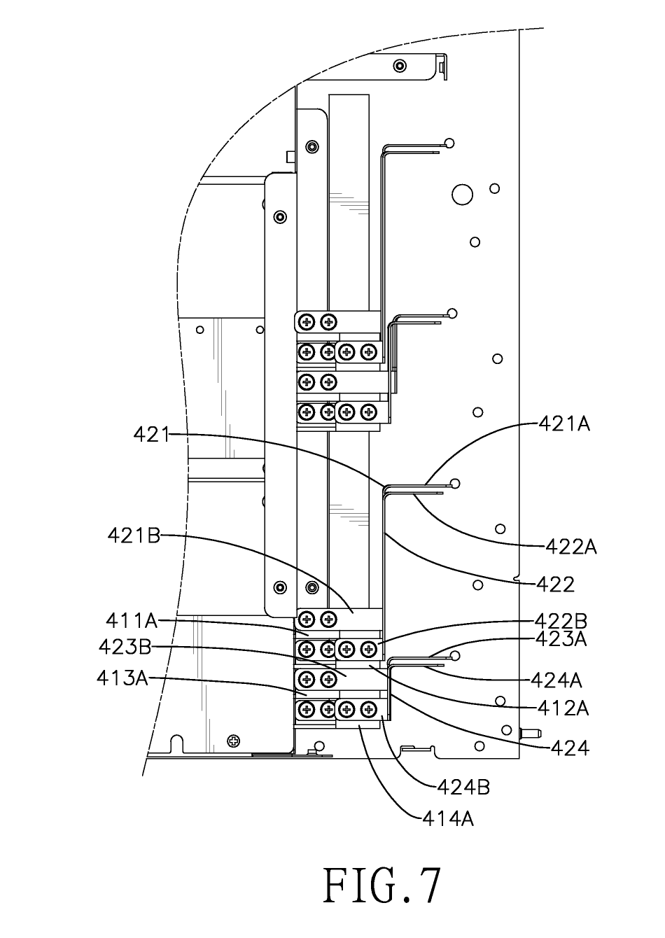

As shown in FIGS. 2 and 7, since the connecting terminals 411, 412, 413, 414 have different lengths and are alternately arranged along a longitudinal direction of the housing 10, the connecting portions 411A, 412A, 413A, 414A of the connecting terminals 411, 412, 413, 414 are alternately arranged in transverse direction of the housing 10. Thus, when the at least one front panel 30 has been mounted on the front 101 of the housing 10, the arrangement of the connecting portions 411A, 412A, 413A, 414A of the connecting terminals 411, 412, 413, 414 provides convenience of connecting the intermediate terminal assemblies 42 to the connecting portions 411A, 412A, 413A, 414A of the connecting terminals 411, 412, 413, 414, such that the conducting terminals 51 of the terminal holders 50 can be electrically connected to the connecting terminal 411, 412, 413, 414 of the connecting terminal assemblies 41.

Specifically, each of the intermediate terminal assemblies 42 includes multiple intermediate terminals 421, 422, 423, 424. Each of the intermediate terminals 421, 422, 423, 424 extends longitudinally and has an upper end, a lower end, an upper connecting portion 421A, 422A, 423A, 424A, and a lower connecting portion 421B, 422B, 423B, 424B. The upper connecting portion 421A, 422A, 423A, 424A transversely protrudes forwardly from the upper end of the intermediate terminal 421, 422, 423, 424. The upper connecting portions 421A, 422A, 423A, 424A of the intermediate terminals 421, 422, 423, 424 respectively connect electrically to the conducting terminals 51 of the terminal holders 50. The lower connecting portion 421B, 422B, 423B, 424B transversely protrudes backwardly opposite to the upper connecting portion 421A, 422A, 423A, 424A from a side edge of the intermediate terminal 421, 422, 423, 424 and is disposed adjacent to the lower end of the intermediate terminal 421, 422, 423, 424.

In the preferred embodiment, the intermediate terminals 421, 422, 423, 424 of each intermediate terminal assembly 42 are two long intermediate terminals 421, 422 and two short intermediate terminals 423, 424. The lower connecting portions 421B, 423B of one of the long intermediate terminals 421 and one of the short intermediate terminals 423 are long lower connecting portions and are respectively connected electrically to the connecting portions 411A, 413A of the short connecting terminals 411, 413. The lower connecting portions 422B, 424B of the other long intermediate terminal 422 and the other short intermediate terminal 424 are short lower connecting portions and are respectively connected electrically to the connecting portions 412A, 414A of the long connecting terminals 412, 414.

It can be seen from the above that the connecting portions 411A, 412A, 413A, 414A of the connecting terminals 411, 412, 413, 414 of each connecting terminal assembly 41 of the power distribution module 40 are alternately arranged in transverse and longitudinal directions of the housing 10. Moreover, since lengths of the intermediate terminals 421, 422, 423, 424 of each intermediate terminal assembly 42 are different and lengths of the lower connecting portions 421B, 422B, 423B, 424B are also different, the lower connecting portions 421B, 422B, 423B, 424B can respectively correspond to and electrically connect to the connecting portions 411A, 412A, 413A, 414A of the connecting terminals 411, 412, 413, 414 for the convenience of connecting the intermediate terminal assemblies 42 to the connecting portions 411A, 412A, 413A, 414A of the connecting terminals 411, 412, 413, 414.

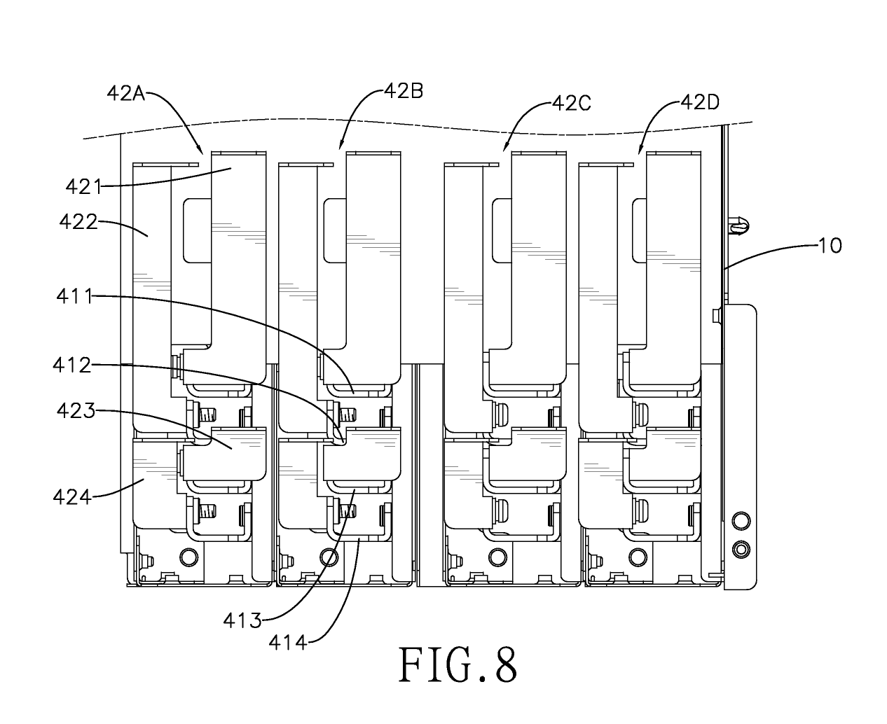

With further reference to FIG. 8, when the at least one front panel 30 has been mounted on the front 101 of the housing 10, the intermediate terminal assemblies 42 can only be mounted into the housing 10 from two opposite sides of the housing 10. The above-mentioned connecting terminal assemblies 41 and intermediate terminal assemblies 42 provide convenience of mounting the intermediate terminal assemblies 42 from the two sides of the housing 10.

Specifically, as shown in FIG. 8, there are four intermediate terminal assemblies 42A, 42B, 42C, 42D mounted in the housing 10. For assembly, a user is able to assemble the intermediate terminal assembly 42B that is disposed second from the left and then assemble the intermediate terminal assembly 42A that is disposed first from the left. Then the user assembles the intermediate terminal assembly 42C that is disposed second from the right and then assembles the intermediate terminal assembly 42D that is disposed first from the right. Thus, the user conveniently assembles the intermediate terminal assemblies 42A, 42B, 42C, 42D into the housing 10. When assembling the intermediate terminal assemblies 42A, 42B, 42C, 42D into the housing 10, the intermediate terminals 421, 422, 423, 424 of the intermediate terminal assemblies 42A, 42B, 42C, 42D respectively connect the connecting terminal assemblies 41 to the conducting terminals 51 of the terminal holders 50.

The server power supply system as described has the following advantages. With the at least one front panel 30 mounted on the front 101 of the housing 10, the peak portions 31 and the valley portions 32 of the at least one front panel 30 form a multi-dimensional space. Thus, heat generated from the terminal holders 50 that are mounted on the first inclined walls 311 of the peak portions 31 can be dissipated from the heat dissipating holes 3120 of the heat dissipating structures on the second inclined walls 312 of the peak portions 31.

Moreover, with the multi-dimensional space formed in the at least one front panel 30 and the heat dissipating holes 3120 of the heat dissipating structures on the second inclined walls 312 of the peak portions 31, as the air current generated by the fan modules 21 of the power supplies 20 flows toward the front 101 of the housing 10, the air current can further flow through the heat dissipating holes 3120 to generate convection and to dissipate the heat in the housing 10. Accordingly, heat dissipating efficiency to the power supplies 20 and the housing 10 is improved.

Furthermore, since the terminal holders 50 are mounted on the first inclined walls 311 of the peak portions 31 of the at least one front panel 30, the valley portions 32 of the at least one front panel 30 provide wiring spaces for disposing the terminal holders 50. Thus, each terminal holder 50 owns an exclusive wiring space not interfered with other terminal holders 50. The at least one front panel 30 not only reconciles both arrangement of the terminal holders and need for dissipating heat, but also provides sufficient wiring spaces to the terminal holders 50.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A server power supply system comprising:
a housing having
a front;
a rear; and
multiple power supply slots disposed on the rear of the housing; and
a front panel mounted on the front of the housing and having multiple peak portions and multiple valley portions;
wherein the peak portions and the valley portions are arranged alternately;
each peak portion has
a first inclined wall;
a second inclined wall;
a holder mounting structure formed on the first inclined wall; and
a heat dissipating structure formed on the second inclined wall.

2. The server power supply system as claimed in claim 1, wherein
the first inclined wall of each peak portion further has an outer surface and an inner surface corresponding to an interior of the housing;
the second inclined wall of each peak portion further has an outer surface and an inner surface corresponding to the interior of the housing;
each peak portion further has a first included angle defined between the inner surface of the first inclined wall and the inner surface of the second inclined wall of the peak portion; and
each valley portion has a second included angle defined between the outer surface of the second inclined wall of one of the peak portions and the outer surface of the first inclined wall of the next peak portion.

3. The server power supply system as claimed in claim 2, wherein
each of the first included angles is 90 degrees; and
each of the second included angles is 90 degrees.

4. The server power supply system as claimed in claim 1, wherein the heat dissipating structure of each peak portion includes multiple heat dissipating holes densely arranged on and formed through the second inclined wall.

5. The server power supply system as claimed in claim 1 further comprising:
multiple terminal holders mounted on the holder mounting structures of the first inclined walls of the peak portions of the front panel, and each terminal holder having
a base securely mounted on the holder mounting structure of the first inclined wall; and
a conducting terminal mounted in the base; and
a power distribution module mounted in the housing and having
multiple circuit boards mounted in the housing;
multiple connecting terminal assemblies respectively connected electrically to the circuit boards; and
multiple intermediate terminal assemblies respectively connecting the conducting terminals of the terminal holders to the connecting terminal assemblies.

6. The server power supply system as claimed in claim 5, wherein each of the connecting terminal assemblies includes multiple connecting terminals, and each of the connecting terminals further has a connecting portion protruding up from a front end of the connecting terminal;
wherein the connecting terminals of each connecting terminal assembly are two short connecting terminals and two long connecting terminals;
the short connecting terminals and the long connecting terminals are alternately arranged along a longitudinal direction of the housing; and
the connecting portions of the short connecting terminals and the long connecting terminals are alternately arranged in a transverse direction of the housing.

7. The server power supply system as claimed in claim 6, wherein each of the intermediate terminal assemblies includes multiple intermediate terminals, and each of the intermediate terminals has
an upper end;
a lower end;
an upper connecting portion transversely protruding forwardly from the upper end of the intermediate terminal, and the upper connecting portions of the intermediate terminals respectively connecting electrically to the conducting terminals of the terminal holders; and
a lower connecting portion transversely protruding opposite to the upper connecting portion from a side edge of the intermediate terminal and disposed adjacent to the lower end of the intermediate terminal;
wherein the intermediate terminals of each intermediate terminal assembly are two long intermediate terminals and two short intermediate terminals;
the lower connecting portions of one of the long intermediate terminals and one of the short intermediate terminals are long lower connecting portions and are respectively connected electrically to the connecting portions of the short connecting terminals; and
the lower connecting portions of the other long intermediate terminal and the other short intermediate terminal are short lower connecting portions and are respectively connected electrically to the connecting portions of the long connecting terminals.

8. The server power supply system as claimed in claim 5, wherein
the first inclined wall of each peak portion further has an outer surface and an inner surface corresponding to an interior of the housing;
the holder mounting structure of each peak portion includes
at least one opening formed through the first inclined wall of the peak portion, and each of the at least one opening of the holder mounting structure being rectangular; and
a mounting panel securely mounted on the inner surface of the first inclined wall of the peak portion; and
the base of each terminal holder is rectangular;
wherein a length of the base corresponds to a width of the opening.

9. The server power supply system as claimed in claim 8, wherein
the conducting terminal of each terminal holder has
a first end securely attached to the base and the mounting panel via fasteners; and
a second end bent relative to the first end of the conducting terminal and protruding through the base and toward the interior of the housing;
each of the terminal holders further has at least one conducting protrusion formed on and protruding from the first end of the conducting terminal.

10. The server power supply system as claimed in claim 1 further comprising multiple power supplies respectively mounted in the power supply slots of the housing, and each of the power supplies having a fan module mounted in an outer end of the power supply.

11. The server power supply system as claimed in claim 2 further comprising multiple power supplies respectively mounted in the power supply slots of the housing, and each of the power supplies having a fan module mounted in an outer end of the power supply.

12. The server power supply system as claimed in claim 3 further comprising multiple power supplies respectively mounted in the power supply slots of the housing, and each of the power supplies having a fan module mounted in an outer end of the power supply.

13. The server power supply system as claimed in claim 4 further comprising multiple power supplies respectively mounted in the power supply slots of the housing, and each of the power supplies having a fan module mounted in an outer end of the power supply.

14. The server power supply system as claimed in claim 5 further comprising multiple power supplies respectively mounted in the power supply slots of the housing, and each of the power supplies having a fan module mounted in an outer end of the power supply.

15. The server power supply system as claimed in claim 6 further comprising multiple power supplies respectively mounted in the power supply slots of the housing, and each of the power supplies having a fan module mounted in an outer end of the power supply.

16. The server power supply system as claimed in claim 7 further comprising multiple power supplies respectively mounted in the power supply slots of the housing, and each of the power supplies having a fan module mounted in an outer end of the power supply.

17. The server power supply system as claimed in claim 8 further comprising multiple power supplies respectively mounted in the power supply slots of the housing, and each of the power supplies having a fan module mounted in an outer end of the power supply.

18. The server power supply system as claimed in claim 9 further comprising multiple power supplies respectively mounted in the power supply slots of the housing, and each of the power supplies having a fan module mounted in an outer end of the power supply.
